(19) United States
(12) Patent Application Publication
(10) Pub. No.: US 2007/0075325 A1
(43) Pub. Date: Apr. 5, 2007

(54) High power light emitting diode package

(75) Inventors: Jong Hwan Baek, Seoul (KR); Je Myung Park, Siheung (KR); Geun Chang Ryo, Siheung (KR); Jun Ho Seo, Seoul (KR); Jung Kyu Park, Seoul (KR)

Correspondence Address: MCDERMOTT WILL & EMERY LLP, 600 13TH STREET, N.W., WASHINGTON, DC, 20005-3096, US

(73) Assignee: SAMSUNG ELECTRO-MECHANICS CO., LTD.

(21) Appl. No.: 11/541,658

(22) Filed: Oct. 3, 2006

(30) Foreign Application Priority Data
Oct. 4, 2005 (KR) 10-2005-0093170

(51) Int. Cl. H01L 33/00

(52) U.S. Cl. 257/99

(57) ABSTRACT

The invention relates to a high power LED package having excellent light efficiency and heat dissipating characteristics. The LED package includes a base member, a reflector unit arranged on the base member and having a plurality of first reflectors, a plurality of LED chips mounted on the base member and surrounded by the first reflectors, and a connection unit arranged on the base member, for electrically connecting the LED chips to an outside. The reflector unit also includes a second reflector surrounding the first reflectors. The second reflector is arranged to surround the first reflectors in order to completely prevent any interference of emission lights and collect the emission lights together, thereby enabling excellent light efficiency. Furthermore, with the first reflectors surrounding the individual LED chips, it is possible to maximize heat dissipating efficiency of the lead frame, thereby stabilizing operating characteristics of the package.

### CLAIM OF PRIORITY

This application claims the benefit of Korean Patent Application No. 2005-93170 filed on Oct. 4, 2005, in the Korean Intellectual Property Office, the disclosure of which is incorporated herein by reference.

### BACKGROUND OF THE INVENTION

1. Field of the Invention

The present invention relates to a high power Light Emitting Diode (LED) package, in particular, which is devised to receive a plurality of LED chips while preventing light interference to further enhance light efficiency, and in which a base member has recesses for seating the LED chips seated therein in order to ensure excellent heat dissipating ability.

2. Description of the Related Art

LEDs are designed to emit light from excessive energy generating when applied electrons recombine with holes. Examples of such LEDs include a red LED based on GaAsP, a green LED based on GaP and a blue LED based on a double hetero structure of InGaN/AlGaN.

The LEDs are widely used in various fields such as a number/character display unit, a traffic lamp, a sensor, a light source for a photo coupler owing to their merits of low supply voltage, low power consumption and so on.

Such LEDs are required to have following qualities: high brightness, long lifetime, thermal stability and operability at a low voltage.

Brightness among the above qualities is closely related with power consumption of a device, and thus various researches are under development to raise the brightness of the LEDs.

The LEDs have a basic structure composed of a GaN buffer layer, an under GaN layer, an n-dopant GaN layer, an active layer and a p-dopant GaN layer sequentially grown on a sapphire substrate.

A Transparent Metal (TM) layer is grown on the p-dopant GaN layer to transmit light from the active layer to the outside.

The LEDs having the above structure operate according to the following principle. When a forward voltage is applied to a semiconductor of a specific element, electrons and holes are recombined through migration in a positive-negative junction. Then, energy level is dropped, thereby emitting light.

In addition, the LEDs are fabricated in a very small size of about 0.25 mm, and mounted on a lead frame via epoxy molding and then on a Printed Circuit Board (PCB).

A most typically used LED is provided in the form of a 5 mm plastic package. However, new types of packages are under development according to specific applications. The composition of a semiconductor chip determines the color of light emitted from an LED according to a specific wavelength.

In particular, LEDs are being further miniaturized as information communication devices are more reduced in size and slimmed, in which elements of the devices such as a resistor, a capacitor and a noise filter are further reduced in size. Recently, the LEDs are produced in the form of Surface Mount Devices (SMDs) to be directly mounted on the PCB.

Accordingly, LED lamps used for display devices are being developed into SMDs. The SMDs can replace conventional lamps, and be used as lighting devices of various colors, a character display unit and an image display unit.

The LEDs are applied to more various fields such as a home lamp and an emergency lamp, which require high brightness. Currently, as a result, high power LEDs are adopted.

For example, a high power LED package has several LEDs mounted to enhance light output. In the high power LED package, red, green and blue LED chips are mounted and molded together to constitute one LED package.

In this case, corresponding number of moldings or molded bodies can be provided according to the colors of the individual LED chips.

As an alternative, several LED chips may be mounted in a single high power LED package.

For example, red, green and blue LED chips may be mounted together in a single molding or molded body.

Then, the individual LED chips are wire-bonded to leads of a distributing unit such as a lead frame, and an encapsulant is provided on the wire-bonded LED chips to produce a high power LED package.

An example of such a conventional high power LED package is shown in FIGS. 1 to 2b.

That is, as shown in FIGS. 1 to 2b, a sloped annular reflector 120 is formed in a lead frame 110, and a plurality of LED chips 130 are mounted inside the reflector 120, electrically connected to leads 140 of the lead frame 110 via wires 150 (i.e., wire bonding).

Another example of the conventional high power LED package is shown in FIGS. 3a and 3b.

That is, as shown in FIGS. 3a and 3b, in this type of conventional high power LED package 200, an annular reflector 220 is arranged around a lead frame 210, and a plurality of LED chips 230 are mounted inside the lead frame 210, electrically connected to leads 240 via wires 250 (i.e., wire bonding).

In the conventional high power LED packages 100 and 200, an encapsulant (not shown) is provided over the LED chips.

When the encapsulant is molded from an epoxy resin as a whole on the plurality of LED chips, the high power LED packages can be produced easily.

In the conventional high power LED package 100, 200, only one sloped annular (or rectangular rim-shaped) reflector 120, 220 is provided irrespective of the lead connection structure. Then, as shown in FIG. 4, lights emitted from adjacent ones of the LED chips 130, 230 interfere with each other, thereby degrading light efficiency as a drawback.

In addition, the high power LED package 100, 200 where several LED chips are mounted have some elements resistant against the LED chips 130, 230, which cause power loss while hindering heat dissipation. The conventional LED package 100, 200 has poor heat dissipating efficiency since the LED chips are mounted inside the reflector of the lead frame.

That is, in a case where several LED chips are mounted inside one molding, a larger amount of heat is emitted but heat dissipation efficiency is rather low.

### SUMMARY OF THE INVENTION

Accordingly, it is desirable to provide an LED package of a dual reflector structure composed of separate reflectors for individual LED chips and another reflector for the entire package.

That is, the dual reflector structure can preferably prevent light interference and raise heat dissipating efficiency with a lead frame having a group of indented recesses.

The present invention has been made to solve the foregoing problems of the prior art and therefore an object of certain embodiments of the present invention is to provide a high power LED package which has first reflectors arranged to correspond to a plurality of LED chips mounted on a single lead frame and a second reflector arranged to surround the first reflectors in order to completely prevent any interference of emission lights and collect the emission lights together, thereby enabling excellent light efficiency.

Another object of certain embodiments of the present invention is to provide a high power LED package in which first reflectors of recesses indented to surround LED chips mounted therein can improve heat dissipating efficiency of a base member, thereby imparting excellent heat dissipating characteristics to the LED package.

According to an aspect of the invention for realizing the object, there is provided a high power LED package comprising: a base member; a reflector unit arranged on the base member, the reflector unit including a plurality of first reflectors and a second reflector surrounding the first reflectors; a plurality of LED chips mounted on the base member and surrounded at least by the first reflectors; and a connection unit arranged on the base member, for electrically connecting the LED chips to an outside.

Preferably, the base member comprises a member capable of dissipating heat, which is selected from a group consisting of a metal lead frame, a metal substrate and a metal-plated resin substrate.

Preferably, each of the first reflectors comprises a separate LED chip reflector which receives each of the LED chip therein so that light reflecting from the received LED chip does not interfere with light reflecting from an adjacent one of the LED chips.

Preferably, the second reflector of the reflector unit is arranged around the first reflectors while forming an enclosed package reflector in order to collect lights emitted from the LED chips and reflecting from the first reflectors around the LED chips.

Preferably, the base member comprises a lead frame, wherein the first and second reflectors of the reflector unit are formed integrally.

Preferably, the base member comprises a substrate on which the first and second reflectors of the reflector unit are mounted.

Preferably, the base member comprises a lead frame, wherein the connection unit comprises a lead attached to the base member with an insulating layer interposed therebetween and bonding wires electrically connecting the lead with the LED chips.

Preferably, the base member comprises a substrate, wherein the connection unit comprises a connection pattern connected with the LED chips which are surface-mounted on the substrate.

Preferably, the first reflectors have a reflect-activating layer formed on a surface thereof to raise reflecting efficiency of light generated from LED chips, and the second reflector has a reflect-activating layer formed on a surface thereof to raise reflecting efficiency of lights generated from the LED chips and reflecting from the first reflectors.

Here, the high power LED package may further comprise a heat sink plate underlying the base member.

In addition, the high power LED package may further comprise an encapsulant applied over the LED chips inside the reflector unit.

### BRIEF DESCRIPTION OF THE DRAWINGS

The above and other objects, features and other advantages of the present invention will be more clearly understood from the following detailed description taken in conjunction with the accompanying drawings, in which:

FIG. 1 is a perspective view illustrating a conventional high power LED package;

FIG. 2a is a cross-sectional view taken along the line A-A′ of FIG. 1;

FIG. 2b is a cross-sectional view taken along the line B-B′ of FIG. 1;

FIG. 3a is a perspective view illustrating another type of conventional high power LED package;

FIG. 3b is a cross-sectional view illustrating the high power LED package shown in FIG. 3a;

FIG. 4 is a fragmentary cross-sectional view illustrating light interference in a conventional LED package as shown in FIG. 1 or FIG. 3a;

FIG. 5 is a perspective view illustrating high power LED package having excellent light efficiency according to the invention;

FIG. 6 is a cross-sectional view taken along the line C-C′ of FIG. 5;

FIG. 7 is a fragmentary cross-sectional view of important parts illustrating light emission from the LED package of the invention;

FIG. 8 is a fragmentary cross-sectional view of important parts illustrating a high power LED package according to another embodiment of the invention; and

FIG. 9 is a cross-sectional view illustrating a high power LED package according to further another embodiment of the invention.

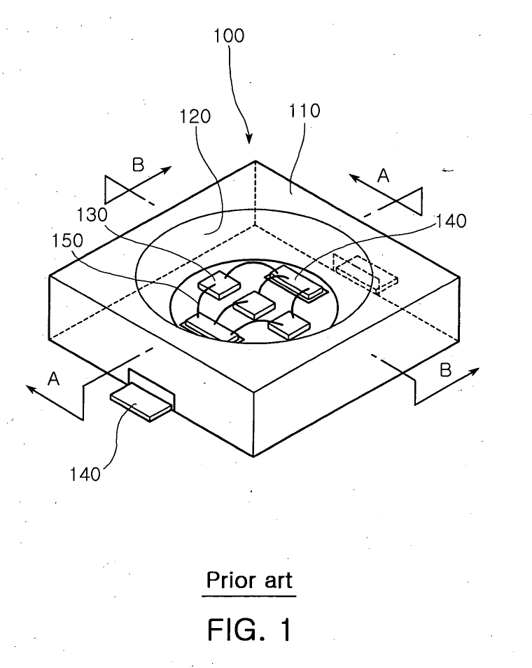

### DETAILED DESCRIPTION OF THE PREFERRED EMBODIMENT

The present invention will now be described more fully hereinafter with reference to the accompanying drawings, in which preferred embodiments of the invention are shown.

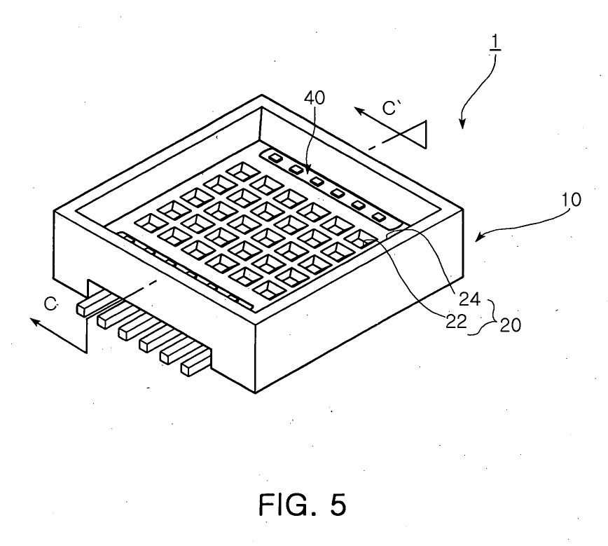

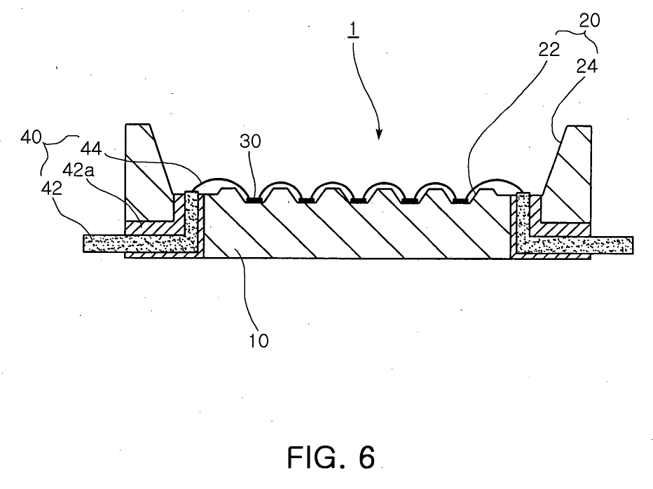

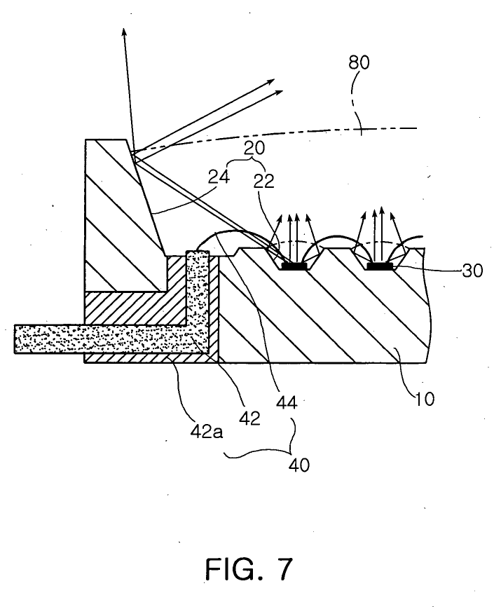

First, FIGS. 5 to 7 show a high power LED package 1 of the invention, in which FIG. 5 illustrates a lead frame or base member when LED chips are not mounted, FIG. 6 is a cross sectional view illustrating a high power LED package of the invention, and FIG. 7 illustrates important parts.

That is, as shown in FIGS. 6 and 7, the high power LED package 1 of the invention generally includes a base member 10, a reflector unit 20 provided on the base member 10, a plurality of LED chips 30 mounted on the base member 10 and surrounded at least by first reflectors 22 of the reflector unit 20 and a connection unit 40 arranged in the base member 10 to electrically connect the LED chips 30 to the outside.

In particular, as a technical feature, the reflector unit 20 also includes a second reflector 24 which surrounds the first reflectors 22.

Accordingly, in the high power LED package 1 of the invention including the base member 10, the reflector unit 20, the LED chips 30 and the connection unit 40, the reflector unit 20 is composed of two types of reflectors, that is, the first reflectors 22 and the second reflector 24.

As will be described in detail hereunder, in the first reflector unit 20 of the LED package 1 of the invention, the first reflectors 22 serve to surround the LED chips 30, respectively, to prevent any interference of lights emitted from adjacent ones of the LED chips 30, and the second reflector 24 serves to focus and collect the entire lights reflecting from the first reflectors 22 and directly emitted from the LED chips 30.

As a result, the LED package 1 of the invention achieves excellent light efficiency.

Describing the features of the invention in detail, the base member 10 of the LED package 1 of the invention is selected from a metal lead frame, a metal substrate and a metal-plated resin substrate, which can at least dissipate or radiate heat outward.

That is, the base member 10 of the invention is made of or plated (coated) with a metal of excellent heat conductivity, and thus can maintain heat dissipating ability when embodied into a high power packet where a plurality of LED chips are mounted.

Also, in the LED package 1 of the invention, each of the LED chips 30 is mounted inside each of the first reflectors 22 of the reflector unit 20 so that light emitted from the each LED chip 30 does not interfere with light emitted from adjacent one. As a result, the each first reflector 22 surrounds the each LED chip 30, thereby forming a separate LED chip reflector.

Now, referring to FIGS. 6 and 7, in a case where at least a plurality of the LED chips 30 are mounted on the high LED package 1, each of the first reflectors 22 surrounds each of the LED chips 30, thereby preventing light emitted from the each LED chip from interfering with light emitted from adjacent one, which otherwise would degrade light efficiency.

In fact, the first reflector 22 is indented into the base member 10 with a slope.

Then, as shown in FIGS. 6 and 7, the second reflector 24 of the reflector unit 20 is arranged around the first reflectors 22, forming an enclosed package reflector in order to collect lights emitted from the LED chips 30 and reflecting from the first reflectors 22 around the LED chips 30.

That is, the second reflector 24 is a structure which does not correspond to the each LED chip 30 but collect whole lights from the package. The second reflector 24 is actually dam-shaped, and has a sloped and enclosed reflecting surface which is located higher than at least the first reflectors 22. The reflecting surface of the second reflector 24 is shown rectangular in the drawings but may be circular (not shown).

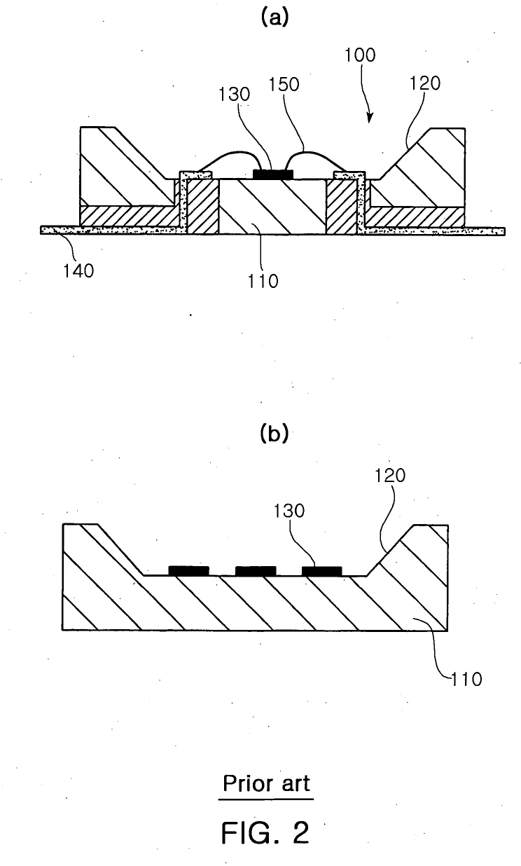

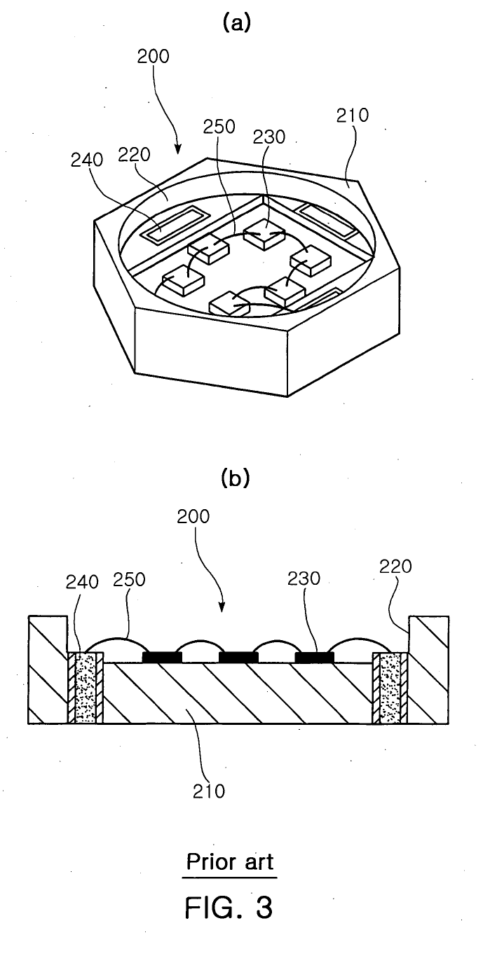

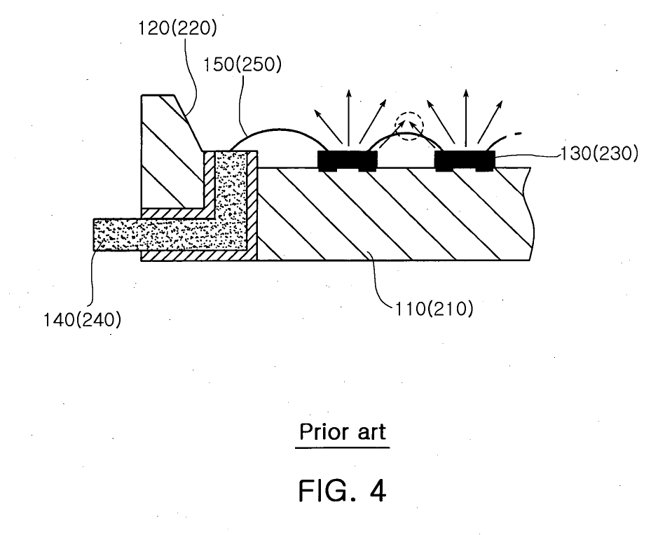

Then, as shown in FIGS. 5 and 7, the base member 10 is configured as a lead frame as shown in FIG. 2, and made of a material capable of dissipating (radiating) heat such as Cu of excellent heat conductivity.

Accordingly, the base member 10 of the lead frame made of Cu can be fabricated with the first and second reflectors 22 and 24 through single punching.

As an alternative, as shown in FIG. 9, a base member 10′ is provided in the form of a substrate such as a metal substrate and a metal-plated resin substrate, in which first and second reflectors are made separately from the base member 10′ and mounted thereon.

For example, in a case where the reflector unit 20 is made of a ceramic of excellent heat resistance, the first reflectors 22 may be made from a single layer ceramic sheet and the second reflector 24 may be made from a multi-layer ceramic structure.

In this case, the chips 30 may be mounted on patterns 46, which are applied on the base member 10′ to serve as a connection unit.

Accordingly, in a case of FIG. 7 where the LED chips 30 are mounted on the lead frame-type base member, the lead frame is mounted on a main board of a device, and the connection unit 40 includes leads 42 attached to the base member 10 with insulating layers 42a interposed therebetween and bonding wires 44 for connecting the leads 42 with the LED chips 30. Then, the leads 42 are connected to an electric pattern on the main board.

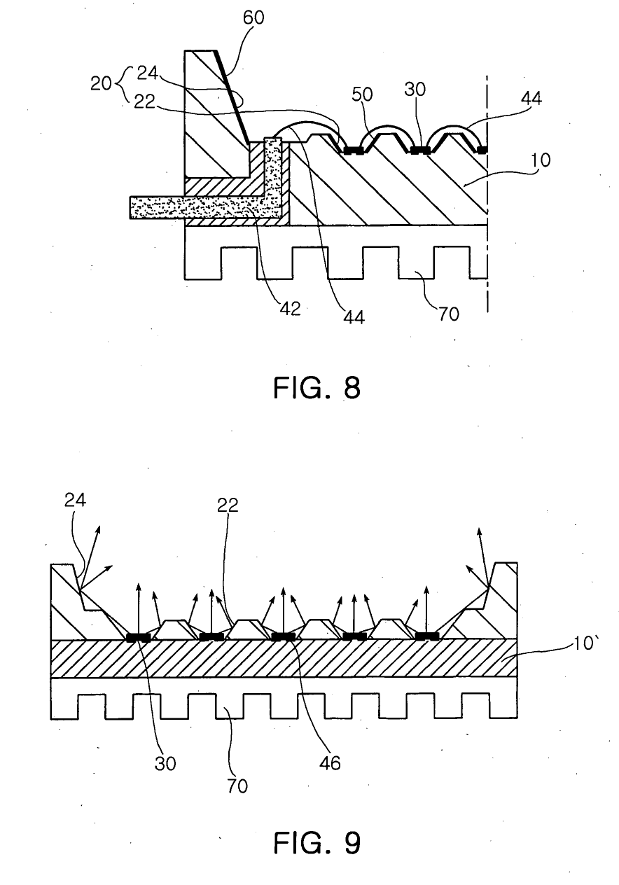

With reference to FIG. 8, another embodiment of the LED package 1 is shown, which further includes a reflect-activating layer 50 formed at least on the surface of the first reflectors 22 to enhance reflecting efficiency.

As an alternative, the reflector 24 may have a reflect-activating layer 60 formed on the surface thereof to enhance the reflecting efficiency of lights emitted from the LED chips 30 and reflecting from the first reflectors.

Otherwise, all of the first and second reflecting layers 22 and 24 may be provided with a reflect-activating layer.

Here, the reflect-activating layer 50, 60 is of a Ag layer having excellent reflectivity, plated on the surface of the first and second reflecting layer 22, 24.

Accordingly, the LED package 1 of the invention with the dual reflecting structure of the first and second reflecting layers 22 and 24 can prevent light interference and achieve more excellent light emitting efficiency through individual reflectors. Moreover, the reflect-activating layer can further enhance light efficiency.

Referring to FIG. 6 again, the high power LED package 1 of the invention has excellent heat dissipating efficiency, which is more excellent in particular when the base member 10 is a lead frame made of Cu.

That is, in a case where the first reflectors 22 in the form of indented recesses are provided in a large number corresponding to the LED chips, heat dissipating area is increased, thereby obtaining excellent heat dissipating characteristics.

Accordingly, the high power LED package 1 of the invention has excellent light efficiency and improved heat dissipating characteristics, which completely satisfy most important two factors for LED packages, thereby improving package reliability.

Reference to FIG. 9 again, a heat radiating plate 70 may be further applied to the underside of the base member 10.

This may further enhance heat dissipating characteristics of the high power LED package 1 of the invention.

Although not shown in the drawings, the LED package of the invention has an encapsulant provided over the LED chips inside the second reflector 24. Such an encapsulant is well known in the art.

According to the high power LED package of the invention as set forth above, the first reflectors are provided corresponding to a plurality of LED chips mounted on a single lead frame and the second reflector is arranged to surround the first reflectors. This as a result can produce light emitting characteristics, which completely prevent light interference and focus emission light, thereby enabling excellent light efficiency.

In particular, since the LED chips are mounted inside the first reflectors in the lead frame, it is possible to maximize heat dissipating efficiency of the lead frame, thereby stabilizing operating characteristics of the package.

While the present invention has been described with reference to the particular illustrative embodiments and the accompanying drawings, it is not to be limited thereto but will be defined by the appended claims. It is to be appreciated that those skilled in the art can substitute, change or modify the embodiments into various forms without departing from the scope and spirit of the present invention.

What is claimed is:

1. A high power light emitting diode package comprising:
a base member;
a reflector unit arranged on the base member, the reflector unit including a plurality of first reflectors and a second reflector surrounding the first reflectors;
a plurality of light emitting diode chips mounted on the base member and surrounded at least by the first reflectors; and
a connection unit arranged on the base member, for electrically connecting the light emitting diode chips to an outside.

2. The high power light emitting diode package according to claim 1, wherein the base member comprises a member capable of dissipating heat, which is selected from a group consisting of a metal lead frame, a metal substrate and a metal-plated resin substrate.

3. The high power light emitting diode package according to claim 1, wherein each of the first reflectors comprises a separate light emitting diode chip reflector which receives each of the light emitting diode chip therein so that light reflecting from the received light emitting diode chip does not interfere with light reflecting from an adjacent one of the light emitting diode chips.

4. The high power light emitting diode package according to claim 1, wherein the second reflector of the reflector unit is arranged around the first reflectors while forming an enclosed package reflector in order to collect lights emitted from the light emitting diode chips and reflecting from the first reflectors around the light emitting diode chips.

5. The high power light emitting diode package according to claim 2, wherein the base member comprises a lead frame, wherein the first and second reflectors of the reflector unit are formed integrally.

6. The high power light emitting diode package according to claim 2, wherein the base member comprises a substrate on which the first and second reflectors of the reflector unit are mounted.

7. The high power light emitting diode package according to claim 1, wherein the base member comprises a lead frame, wherein the connection unit comprises a lead attached to the base member with an insulating layer interposed therebetween and bonding wires electrically connecting the lead with the light emitting diode chips.

8. The high power light emitting diode package according to claim 1, wherein the base member comprises a substrate, wherein the connection unit comprises a connection pattern connected with the light emitting diode chips which are surface-mounted on the substrate.

9. The high power light emitting diode package according to claim 3, wherein the first reflectors have a reflect-activating layer formed on a surface thereof to raise reflecting efficiency of light generated from light emitting diode chips.

10. The high power light emitting diode package according to claim 4, wherein the second reflector has a reflect-activating layer formed on a surface thereof to raise reflecting efficiency of lights generated from the light emitting diode chips and reflecting from the first reflectors.

11. The high power light emitting diode package according to claim 1, further comprising a heat sink plate underlying the base member.

12. The high power light emitting diode package according to claim 1, further comprising an encapsulant applied over the light emitting diode chips inside the reflector unit.
